(19) United States
(12) Patent Application Publication
(10) Pub. No.: US 2025/0192724 A1
(43) Pub. Date: Jun. 12, 2025

(54) POWER AMPLIFIER SYSTEM

(71) Applicant: Qorvo US, Inc., Greensboro, NC (US)

(72) Inventor: Nadim Khlat, Cugnaux (FR)

(21) Appl. No.: 19/054,053

(22) Filed: Feb. 14, 2025

Related U.S. Application Data
(63) Continuation of application No. 17/579,796, filed on Jan. 20, 2022, now Pat. No. 12,267,046.
(60) Provisional application No. 63/149,556, filed on Feb. 15, 2021.

(51) Int. Cl. H03F 1/02; H03F 3/21

(52) U.S. Cl. CPC H03F 1/0233; H03F 1/0288; H03F 3/21; H03F 2200/105

(57) ABSTRACT

A power amplifier system having a carrier amplifier having a first supply node, a peaking amplifier having a second supply node, and envelope tracking (ET) circuitry is disclosed. The ET circuitry has a first tracking amplifier that generates a first voltage signal at the first supply node, a second tracking amplifier that generates a second voltage signal at the second supply node, and a transistor coupled between the first supply node and the second supply node. A control circuit has a first input coupled to an output of both or either of the first tracking amplifier and the second tracking amplifier and a control output terminal coupled to a control input terminal of the transistor, wherein the control circuit is configured to progressively turn on the transistor to pass current from the first supply node to the second supply node as the peaking amplifier progressively becomes active.

### RELATED APPLICATIONS

This application is a continuation of U.S. patent application Ser. No. 17/579,796, filed Jan. 20, 2022, which claims the benefit of provisional patent application Ser. No. 63/149,556, filed Feb. 15, 2021, the disclosures of which are hereby incorporated herein by reference in their entireties.

### FIELD OF THE DISCLOSURE

The present disclosure relates generally to radio frequency transmitters and, more particularly, to envelope tracking circuits that control Doherty-type power amplifiers within radio frequency transmitters.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by wireless communication technologies, such as wireless fidelity (Wi-Fi), long-term evolution (LTE), and fifth-generation new-radio (5G-NR). To achieve the higher data rates in mobile communication devices, sophisticated power amplifiers may be employed to increase output power of radio frequency (RF) signals (e.g., maintaining sufficient energy per bit) communicated by mobile communication devices.

Various power amplifier arrangements have been proposed and implemented in transmitter chains within the mobile communication devices to provide the desired output power while also meeting the power level control requirements of 5G-NR. One such power amplifier arrangement is the Doherty amplifier, which uses a carrier amplifier to operate at voltages up to the average power and uses the carrier amplifier and a peaking amplifier to operate at voltages between the average power and a peak power. While the Doherty amplifier provides options for providing power amplification, there remains room for improved energy efficiency and linearity during power amplification.

### SUMMARY

A power amplifier system having a carrier amplifier having a first supply node, a peaking amplifier having a second supply node, and envelope tracking (ET) circuitry is disclosed. The ET circuitry has a first tracking amplifier that generates a first voltage signal at the first supply node, a second tracking amplifier that generates a second voltage signal at the second supply node, and a transistor coupled between the first supply node and the second supply node and a control input terminal. The first tracking amplifier and the second tracking amplifiers may also be referred to as parallel amplifiers. A control circuit has a first input coupled to an output of both or either of the first tracking amplifier and the second tracking amplifier and a control output terminal coupled to a control input terminal of the transistor, wherein the control circuit is configured to progressively turn on the transistor to pass current from the first supply node to the second supply node as the peaking amplifier progressively becomes active.

This disclosure relates to envelope tracking operation with barely Doherty power amplifiers for additional enhanced transmitter efficiency, where a barely Doherty amplifier shows an increase of about 5% extra power-added efficiency versus average power tracking amplifiers, and where the combined barely Doherty with envelope tracking shows about +18% extra power-added efficiency versus average power tracking amplifiers.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of a power amplifier system that includes envelope tracking circuitry that is configured in accordance with the present disclosure to generate two modulated supply voltages from a single tracker circuit that energizes a Doherty power amplifier.

FIG. 2A is a graph showing peaking current of the peaking amplifier versus main current of the carrier amplifier for the Doherty amplifier of FIG. 1.

FIG. 2B is a graph showing voltages for the peaking amplifier and the carrier amplifier versus carrier amplifier current for the Doherty amplifier of FIG. 1.

FIG. 3 is a graph showing power supply voltage (Vcc) carrier and Vcc peaking swings for an Ideal Doherty amplifier.

FIG. 4 is a graph showing Vcc carrier and Vcc peaking swings for the Doherty amplifier of FIG. 1.

FIG. 5 is a graph illustrating efficiency improvements provided by the power amplifier system of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to envelope tracking integrated circuits (ETICs) with an approach referred to as DiVeRT, which stands for Dual instantaneous Voltage enhanced Rapid Tracking, which creates two simultaneous modulated power supply voltages from a single tracker circuit and thus enables new power amplifier topologies of modulating the collector of power amplifiers.

Separately modulating the driver stage from the final output stages of power amplifiers allows wide modulation bandwidth ET such as ET 200 MHZ, where the modulation of the first driver stage has the corresponding Vcc time-aligned to the radio frequency (RF) envelope and where the modulation of the final stages has the corresponding Vcc time-aligned to the RF envelope, which usually is slightly delayed by interstage networks.

Separately modulating the carrier amplifier stages and the peaking amplifier stages for a barely Doherty (or load modulation) power amplifier, that is, the separate envelope tracking of carrier and peaking amplifiers, enables additional bias control of these two amplifier stages almost for free and minimizes degradation due to turn-on or turn-off of the peaking amplifier and enhances efficiency in addition to the load modulation itself and recovers the efficiency drop due to the use of barely Doherty approach. This is called D²E, which stands for Doherty and dual ET method in accordance with the present disclosure.

Modulating two power amplifiers used in transmit (TX) diversity transmitting at either similar power or at different power levels the same RF modulation signal allows operation with a traditional approach of modulating both driver and final output stages of power amplifiers in different modes of ET, such as ProET (progressive Voffset (e) envelope tracking) or normal ET, or of average power tracking (APT), or APeT, which stands for operating in ET while using the APT controller with a tracking amplifier disabled.

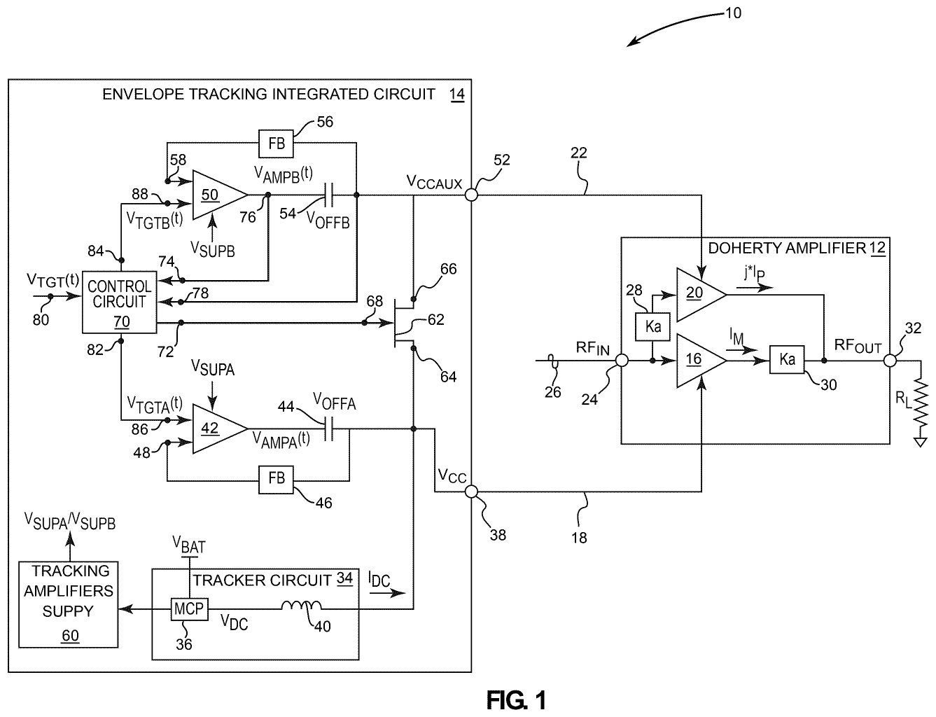

FIG. 1 is a schematic diagram of a power amplifier system 10 that in accordance with the present disclosure includes a Doherty power amplifier (PA) 12 and envelope tracking (ET) circuitry 14. In the exemplary embodiment of FIG. 1, the envelope tracking circuitry 14 is in the form of an ETIC.

The Doherty PA 12 has a carrier amplifier 16 having a first supply node 18 and a peaking amplifier 20 having a second supply node 22. The Doherty PA 12 has a radio frequency (RF) signal input 24 that couples an RF signal 26 to the carrier amplifier 16 and the peaking amplifier 20. However, the RF signal 26 passes through a first impedance inverter 28 denoted “Ka” before reaching the peaking amplifier 20. In operation, the carrier amplifier 16 generates a main current signal IM that passes through a second impedance inverter 30 before reaching an RF output 32. The peaking amplifier 20 generates a peaking current signal j*Ip that combines in-phase with the main current signal I_{M} before being output through the RF output 32. A load R_{L} is coupled between the RF output 32 and a fixed voltage node such as ground. The load R_{L} is typically an antenna through which an amplified version of the RF signal 26 is transmitted.

A single tracker circuit 34 of the ET circuitry 14 supplies power to the Doherty amplifier 12. The single tracker circuit 34 is configured to generate two modulated Vcc supply voltages, Vcc and Vccaux. A micro-charge-pump (MCP) 36 has an output coupled to a first supply output 38 through a power inductor 40. The MCP 36 is energized by a battery voltage V_{BAT}. The first supply node 18 is coupled to the first supply output 38 to supply power the carrier amplifier 16.

The ET circuitry 14 also includes a first tracking amplifier 42 coupled to the first supply output 38 by way of a relatively large capacitance (˜2.2 μF) of a first offset capacitor 44. A first offset voltage V_{OFFA} is present across the first offset capacitor 44 during operation. A first feedback (FB) network 46 is coupled between the first supply output 38 and a first tracking input 48 of the first tracking amplifier 42.

The ET circuitry 14 also includes a second tracking amplifier 50 coupled to a second supply output 52 by way of a relatively small capacitance (˜10 nF) of a second offset capacitor 54. A second offset voltage V_{OFFB} is present across the second offset capacitor 54 during operation. A second feedback (FB) network 56 is coupled between the second supply output 52 and a second tracking input 58 of the second tracking amplifier 50. The second supply node 22 is coupled to the second supply output 52 to supply power the peaking amplifier 20.

A tracking amplifiers supply 60 generates a first tracking amplifier supply voltage V_{SUPA} that energizes the first tracking amplifier 42. The tracking amplifiers supply 60 also generates a second tracking amplifier supply voltage V_{SUPB} that energizes the second tracking amplifier 50. In some embodiments, the MCP 36 may supply a direct current voltage that the tracking amplifiers supply 60 uses to generate the first tracking amplifier supply voltage V_{SUPA} and second tracking amplifier supply voltage V_{SUPB}.

A field effect transistor (FET) 62 has a first current terminal 64 coupled to the first supply node 18 through the first output 38. The FET 62 also has a second current terminal 66 coupled to the second supply node 22 through the second supply output 52. A control terminal 68 is used to control the FET 62. A control circuit 70 has a control output 72 coupled to the control terminal 68, wherein the control circuit 70 is configured to control the FET 62 to behave as a current source in a linear mode or as a closed switch or as an open switch. In at least some embodiments, the control circuit 70 includes a digital processor configured to read values from look-up tables, apply the values to digital-to-analog converters, and read signal values from analog-to-digital converters. In the exemplary embodiment of FIG. 1, the control circuit 70 has a first sense input 74 coupled to a tracking output 76 of the second tracking amplifier 50 and a second sense input 78 coupled to the second supply output 52. A differential sensed voltage between the first sense input 74 and the second sense input 78 is equal to the second offset voltage V_{OFFB}.

An external transceiver produces a target Vramp modulation signal V_{TGT(t)} that is received at a Vramp input 80 of the control circuit 70. The control circuit 70 is configured to respond to the target Vramp modulation signal V_{TGT(t)} by simultaneously generating a first target signal V_{TGTA(t)} at a first target signal output 82 and a second target signal V_{TGTB(t)} at a second target signal output 84. The first target signal V_{TGTA(t)} and the second target V_{TGTB(t)} can have different amplitude shapes and different time alignment relative to each other. The first target signal output 82 is coupled to a first target signal input 86 of the first tracking amplifier 42. In response, the first tracking amplifier 42 generates a first tracking amplifier signal V_{AMPA(t)}. The second target signal output 84 is coupled to a second target signal input 88 of the second tracking amplifier 50. In response, the second tracking amplifier 50 generates a second tracking amplifier signal V_{AMPB(t)}. Both the first supply voltage Vcc and the second supply voltage Vccaux track the first tracking amplifier signal V_{AMPA(t)} and the second tracking amplifier signal V_{AMPB(t)}.

During operation of the Doherty amplifier 12, the envelope of the RF voltage across the carrier amplifier 16 is called Vm and the associated current is denoted I_{M}. The envelope of the RF voltage across the peaking amplifier is called Vp and the associated current is denoted j*Ip, where j is the imaginary component showing a 90 degree phase difference between the peaking current Ip and the main current I_{M}. Moreover, for the Doherty amplifier 12 is operated as a barely Doherty power amplifier with assumptions that the load-line transformations are not necessarily the same between the two amplifier stages.

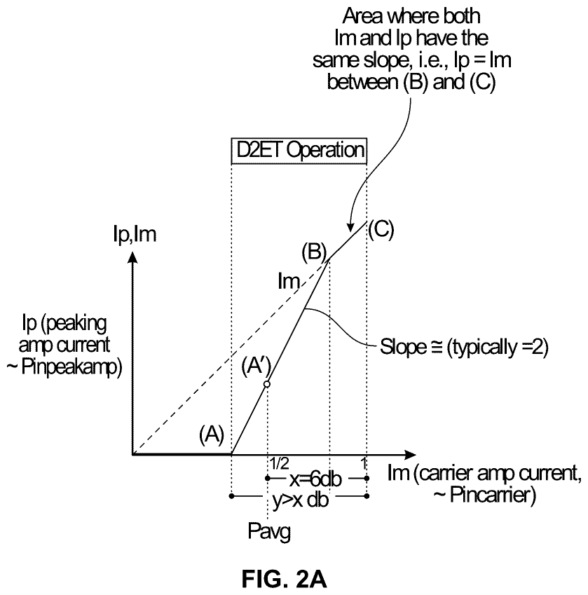

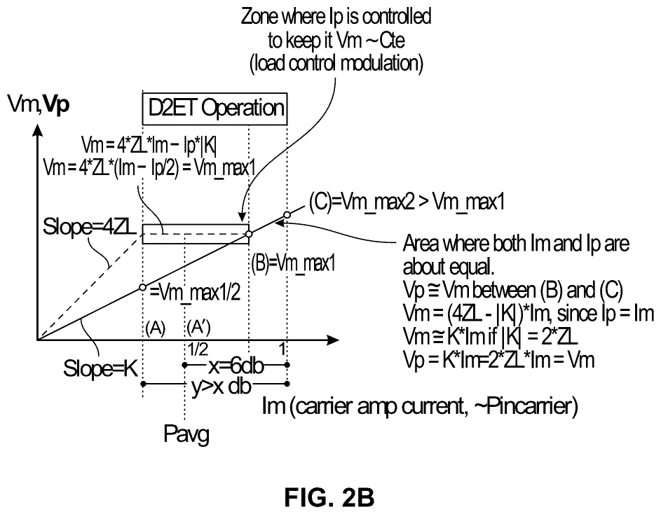

FIGS. 2A and 2B show various currents and voltages in the case of the Doherty amplifier 12 being in operation using the D²E method in which the peaking amplifier 20 is activated much lower than the −6 dB point relative to the peak envelope; that is, the Doherty operation of load-line modulation terminates or expires well below the peak envelope power and then both the carrier and peaking amplifiers each deliver half of the power between point B and point C.

The average point of the modulation does not necessary fall at point A but can fall in between where the load modulation already has reduced the maximum impedance seen by the carrier amplifier at point A′, thus reducing the load modulation efficiency enhancement and thus taking advantage of having envelope tracking on the carrier amplifier 16 to recover efficiency versus an ideal Doherty amplifier.

The peaking amplifier 20 sees different modulation RF voltages when it is activated and can therefore take advantage of having a separate ET modulation on the peaking amplifier 20. The voltage seen by the peaking amplifier 20 at point A is equal to about one half of the voltage seen by the carrier amplifier 16 at point A, and the voltage seen by the peaking amplifier 20 at point B is equal to the same voltage seen by the carrier amplifier 16 at point B, which is twice the voltage at the peaking amplifier 20 at point A. Voltage seen by the carrier amplifier 16 from point B to point C is similar to the voltage seen by the carrier amplifier 20 at these points.

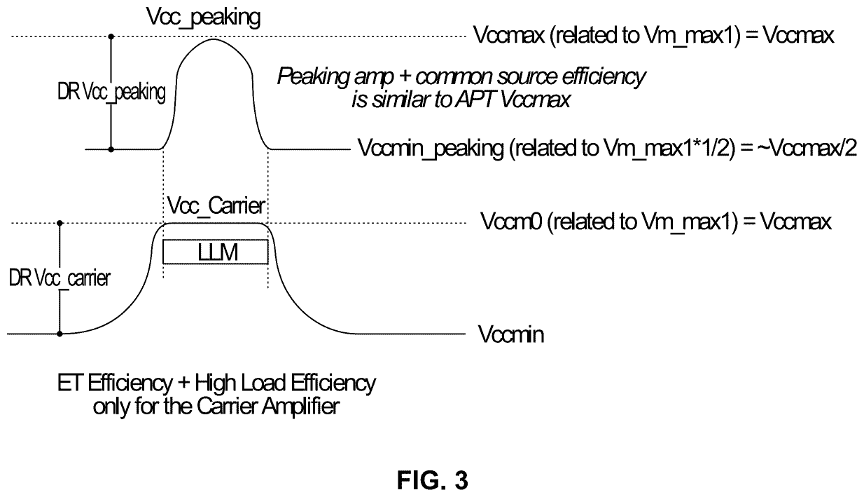

In the case of a modulation signal of peak-to-average ratio of 6 dB and an ideal Doherty case, FIG. 3 shows the modulated Vcc voltages for the carrier amplifier 16 and peaking amplifier 20, where the modulation voltage swing of Vcc_peaking expected by the peaking amplifier is about Vccmax/2 to Vccmax. In the case of the Doherty amplifier 12 being operated as a barely Doherty power amplifier, the modulation voltages change since the load modulation is activated early in time and expires before the peak envelope of the RF modulation is reached.

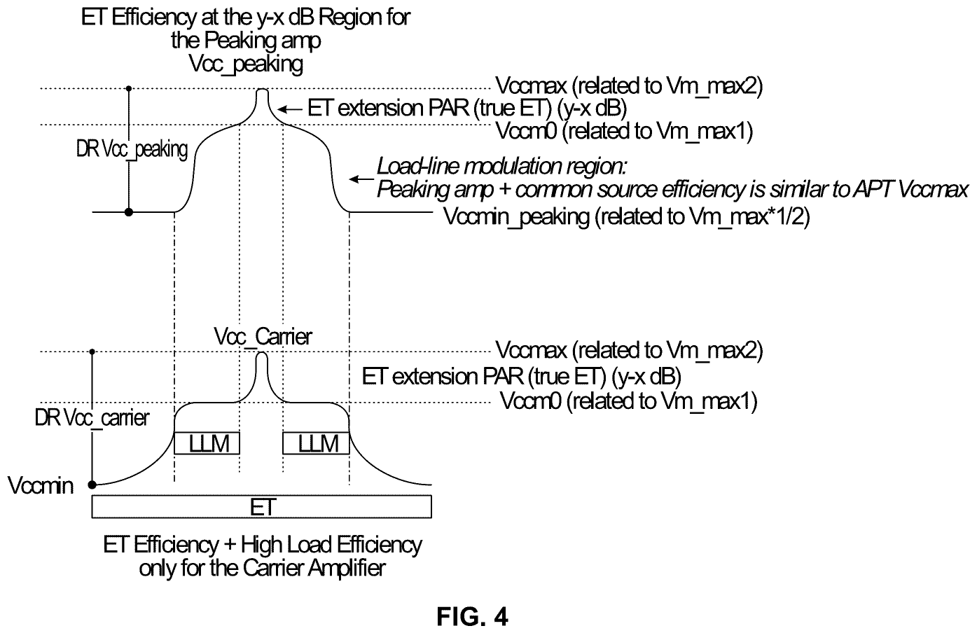

As shown in FIG. 4, the modulation of the supply voltage Vcc on the peaking amplifier 20 has a lower dynamic range versus the modulation of the supply voltage Vcc of the carrier amplifier 16. This is because the minimum voltage is roughly a voltage equal to Vccm0/2 depicted in FIG. 4. Thus, the second offset capacitor 54 can be pre-charged to a value near Vccm0/2 to supply the second tracking amplifier 50 that drives the supply of the peaking amplifier 20 from a lower voltage supply for improved efficiency. Two separate Vcc modulation voltages Vcc_carrier(t)≥Vcc_peaking(t) allow different load-line conversions and/or two different impedance inverter ratios on each of the carrier amplifier 16 and the peaking amplifier 20. As a result of this flexibility, power efficiency may be maximized.

There may be different linearizations by way of the different supply voltages for the carrier amplifier 16 and the peaking amplifier 20 to maximize the overall linearity of the Doherty amplifier 12. For example, the carrier supply modulation Vcc_carrier(t) can be adjusted in proportion to values stored in an envelope tracking look-up table (ET-LUT) that provides isometric gain operation of the carrier amplifier 16. the peaking supply modulation Vcc_peaking(t) can have another ET-LUT relation relative to the carrier supply modulation Vcc_carrier that allows isometric gain operation of the peaking amplifier 20, such that the overall gain of the Doherty amplifier 12 is linearized by taking advantage of the available two modulated supplies. The Vcc_peaking ET-LUT change relative to the ET-LUT relation vs Vcc_carrier can be implemented inside the ET circuitry 14 directly, which uses the input modulated Vramp signal that is used by the Vcc_carrier as target and modifies this via a built-in mapping change to create another target signal for the Vcc_peaking, as shown in FIG. 1.

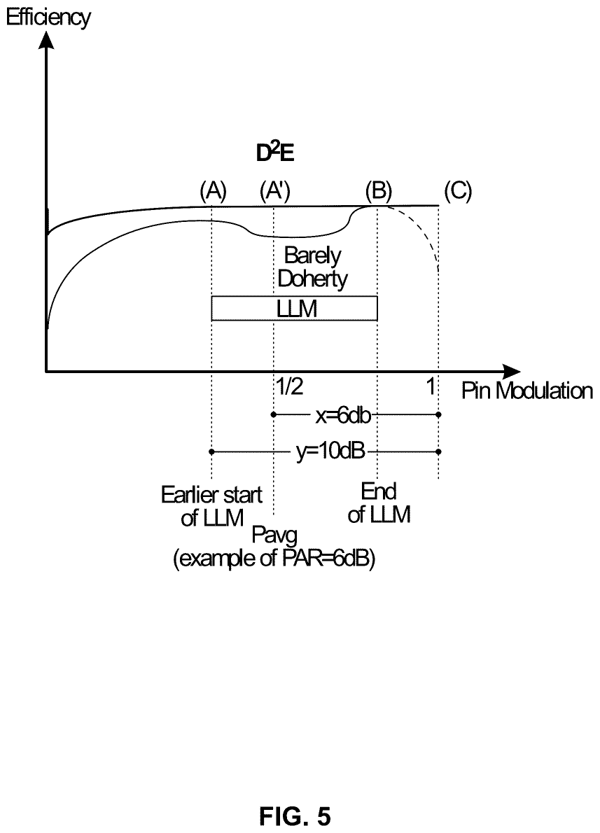

FIG. 5 illustrates the efficiency improvements expected, below point A, between the two peaking points A and B, and above point B. The efficiency of the carrier amplifier 16 is good, given the high load line seen in point A and still some good efficiency at point A′, although the load line had dropped at point A′ due to the barely operation but is improved due to the modulated supply ET operation of the Vcc_carrier between point A and point C to keep operating near compression.

The efficiency of the peaking amplifier 20 is good, but the difference between (Vm(t)−Vp(t)), which represents the voltage across the FET element between Vcc(t) and Vccaux(t) of the ETIC, is dissipating the power for the modulated peaking current that flows through this FET, thus providing the equivalent of having the peaking amplifier supplied from Vccm0 voltage all the time between point A and point B.

The peaking amplifier 20 is biased with a lower supply Vccmin_peaking at the start, where the peaking amplifier is activated and the control of the Vcc_peaking voltage allows better control the RF performances of the peaking amplifier 20 and assigns better bias control at the gate/base and the collector (not shown) versus only bias control on the gate/base of the RF transistors (not shown). The minimum Vcc for the Vcc_peaking can be different from the minimum Vcc_carrier if this helps to better optimize the behavior of the peaking amplifier 20 when it starts or stops to source RF current. The minimum Vcc can also be around half of the Vcc_carrier voltage at the transition point where the peaking amplifier 20 is engaged given that Vp envelope is one half of the Vm envelope. Indirectly, the carrier amplifier 16 and the peaking amplifier 20 can be linearized since each has its own modulated Vcc waveforms that are adjust by values from each ET-LUT.

Note that in embodiments of the present disclosure, the carrier amplifier modulated supply voltage Vcc_carrier (t) is always greater than or equal to the peaking amplifier modulated supply voltage Vcc_peaking (t). Thus, the embodiments of the present disclosure are configured for the DiVeRT approach where Vcc(t)≥Vccaux(t) is required.

Furthermore, the the carrier amplifier modulated supply voltage Vcc_carrier (t) has a low peak-to-average ratio and a lower peak-to-minimum voltage ratio. Thus, the tracker amplifier supply voltage V_{SUPA} for the first tracking amplifier 42 may be lower, which increases the energy efficiency of the envelope tracker circuitry 14. Moreover, the peaking amplifier modulated supply voltage Vcc_peaking (t) for the peaking amplifier 20 has a reduced peak-to-minimum voltage ratio swing. The presence of two different voltages V_{SUPA} less than V_{SUPB} used to differently supply the the first tracking amplifier 42 and the second tracking amplifier 20, respectively, provides for the maximum energy efficiency for the ET circuitry 14.

There may be a mix and match of different power amplifier topologies using Vcc and Vccaux supply voltages. Further, there may be different time alignment between the Vcc_carrier(t) and Vcc_peaking(t), if there is any mismatch in time between the two RF envelopes at each power amplifier. Each power amplifier stage can be biased in class-AB and take advantage of ET amplitude modulation-amplitude modulation linearization of each amplifier via the respective supply path.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method of operating a power amplifier system that includes a carrier amplifier having a first supply node, a peaking amplifier having a second supply node, and envelope tracking (ET) circuitry having a first tracking amplifier, a second tracking amplifier, a transistor, and a control circuit, the method comprising:
generating a first voltage signal at the first supply node using the first tracking amplifier;
generating a second voltage signal at the second supply node using the second tracking amplifier; and
progressively turning on the transistor using the control circuit to pass current from the first supply node to the second supply node as the peaking amplifier becomes active, causing a rate of change of peaking current supplying the peaking amplifier to be greater than a rate of change of carrier current supplying the carrier amplifier.

2. The method of claim 1 further comprising determining by way of the control circuit that the peaking amplifier is becoming increasingly active by monitoring a tracking output voltage at the first input of the control circuit.

3. The method of claim 2 wherein the control circuit has a second input coupled to the second supply node to monitor voltage at the second supply node.

4. The method of claim 3 further comprising monitoring by way of the control circuit a differential voltage between the first input and the second input and in response progressively turns on the transistor to pass current from the first supply node to the second supply node as the peaking amplifier progressively becomes active.

5. The method of claim 1 wherein the first voltage signal has a first amplitude modulation that follows the envelope of a radio frequency signal received by the ET circuitry and the second voltage signal has a second amplitude modulation that follows the envelope of the radio frequency signal received by the ET circuitry.

6. The method of claim 1 further comprising maintaining by way of the control circuit the rate of change of peaking current supplying the peaking amplifier to be greater than the rate of change of carrier current supplying the carrier amplifier until the carrier current and the peaking current are substantially equal.

7. The method of claim 1 wherein the rate of change of peaking current supplying the peaking amplifier has a slope that is at least twice a slope of the rate of change of the carrier current supplying the carrier amplifier.

8. The method of claim 1 wherein the ET circuitry is integrated into an ET integrated circuit (ETIC).

9. The method of claim 1 further comprising ensuring by way of the ET circuitry that a voltage at the first supply node supplying the carrier amplifier remains greater than or equal to a voltage at the second supply node supplying the peaking amplifier.

10. The method of claim 1 wherein the ET circuitry comprises a tracker circuit having a micro-charge-pump with an output coupled to the first supply node through a power inductor.

11. The method of claim 1 wherein the transistor is a field-effect transistor.

12. The method of claim 1 further comprising operating the carrier amplifier and the peaking amplifier in a Doherty amplifier configuration.

13. The method of claim 12 further comprising performing impedance inversion by way of a first impedance inverter coupled between a signal output of the carrier amplifier and a signal output of the peaking amplifier.

14. The method of claim 13 further comprising performing impedance inversion by way of a second impedance inverter coupled between the signal input of the carrier amplifier and the signal input of the peaking amplifier.

15. The method of claim 14 wherein the first impedance inverter and the second impedance inverter have substantially different impedance inverter ratios.

16. The method of claim 1 further comprising providing a first offset voltage across a first capacitor coupled between an output of the first tracking amplifier and the first supply node.

17. The method of claim 16 further comprising providing a second offset voltage across a second capacitor coupled between an output of the second tracking amplifier and the second supply node.

18. The method of claim 16 wherein capacitance of the second capacitor is an order of magnitude less than capacitance of the first capacitor.

19. The method of claim 1 further comprising adjusting supply voltage at the first supply node by way of the control circuit based on values stored in a first envelope tracking look-up table (ET-LUT) to provide isometric gain operation of the carrier amplifier.

20. The method of claim 1 further comprising adjusting supply voltage at the second supply node by way of the control circuit based on values stored in a second ET-LUT to provide isometric gain operation of the peaking amplifier.
